(19) United States
(12) Patent Application Publication
(10) Pub. No.: US 2018/0294158 A1
(43) Pub. Date: Oct. 11, 2018

(54) SEMICONDUCTOR ON INSULATOR SUBSTRATE

(71) Applicant: The Silanna Group Pty Ltd, Eight Mile Plains, Queensland (AU)

(72) Inventors: Andrew Brawley, Cecil Hills (AU); Gary Lim, Ryde (AU); George Imthurn, San Diego, CA (US)

(73) Assignee: The Silanna Group Pty Ltd, Eight Mile Plains, Queensland (AU)

(21) Appl. No.: 15/781,062

(22) PCT Filed: Nov. 8, 2016
(86) PCT No.: PCT/IB2016/056720

§ 371 Date: Jun. 1, 2018

Related U.S. Application Data
(60) Provisional application No. 62/275,103, filed on Jan. 5, 2016.
(60) Provisional application No. 62/263,504, filed on Dec. 4, 2015.

(51) Int. Cl. H01L 21/265; H01L 21/02; H01L 21/762; H01L 21/3065

(52) U.S. Cl. CPC H01L 21/26533; H01L 21/02238; H01L 21/3065; H01L 21/76254; H01L 21/76243

(57) ABSTRACT

Various semiconductor wafers and their methods of fabrication are disclosed. One exemplary process comprises, forming a layer consisting essentially of aluminum nitride on a first wafer. The first wafer includes a substrate. The process also comprises bonding a second wafer to the first wafer. The aluminum nitride layer is interposed between the substrate and the second wafer after the bonding step. The process also comprises separating the first and second wafers to form a semiconductor on insulator (SOI) wafer. The SOI receives a layer of semiconductor material from the second wafer during the separating step. The SOI wafer includes the layer of semiconductor material, the layer consisting essentially of aluminum nitride, and the substrate after the separating step.

### CROSS-REFERENCE TO RELATED APPLICATIONS

This patent application claims the benefit of U.S. Provisional Patent Application No. 62/263,504, filed on Dec. 4, 2015, and U.S. Provisional Patent Application No. 62/275,103, filed on Jan. 5, 2016, which are both incorporated by reference in their entirety herein for all purposes.

### BACKGROUND

Semiconductor-on-insulator (SOI) technology was first commercialized in the late 1990s. The defining characteristic of SOI technology is that the semiconductor region in which circuitry is formed is isolated from a bulk substrate by an electrically insulating layer. This insulating layer is typically silicon-dioxide. The reason silicon-dioxide is chosen is that it can be formed on a wafer of silicon by oxidizing the wafer and is therefore amenable to efficient manufacturing. The advantageous aspects of SOI technology stem directly from the ability of the insulator layer to electronically isolate the active layer from bulk substrate. The active layer is the region in which the circuitry will be formed. As such, the active layer includes a high quality semiconductor material that can be used to create active devices such as transistors. The high quality semiconductor material is referred to as device quality material.

SOI technology represents an improvement over traditional bulk substrate technology because the introduction of the insulating layer isolates the active devices in an SOI structure which improves their electrical characteristics. However, the increase in device performance is partially offset by decreased heat dissipation in the overall SOI wafer. As mentioned previously, silicon-dioxide is the ubiquitous insulator layer in modern SOI technology. At a temperature of 300 degrees Kelvin (K), silicon-dioxide has a thermal conductivity of roughly 1.4 Watts per meter per Kelvin (W/m*K). A bulk silicon substrate at the same temperature has a thermal conductivity of roughly 130 W/m*K. The nearly 100-fold reduction in heat dissipation performance exhibited by SOI technology is highly problematic. A high level of heat in an integrated circuit can shift the electrical characteristics of its devices outside an expected range causing critical design failures. Left unchecked, excess heat in a device can lead to permanent and critical failures in the form of warping or melting materials in the device's circuitry. This effect is particularly problematic in the field of power electronics as the active circuits in a power circuit can be required to sink system level currents and are required to dissipate large amounts of heat.

### BRIEF DESCRIPTION OF THE DRAWINGS

FIG. 1 is a flow chart of methods for fabricating semiconductor on insulator (SOI) structures that are in accordance with some embodiments.

FIG. 2 is a block diagram of a first wafer undergoing an implant species implant in accordance with one or more of the processes of FIG. 1.

FIG. 3 is a block diagram of a first wafer on which a layer of insulating material is being formed in accordance with one or more of the processes of FIG. 1.

FIG. 4 is a block diagram of a first wafer on which an adhesion layer is being formed in accordance with one or more of the processes of FIG. 1.

FIG. 5 is a block diagram of a second wafer being bonded to the first wafer of FIG. 4 in accordance with one or more of the processes of FIG. 1.

FIG. 6 is a flow chart of methods for edge trimming and separating the first and second wafers described in the flow chat of FIG. 1.

FIG. 7 is a block diagram of the first and second wafers of FIG. 5 after being bonded, inverted, and edge trimmed in accordance with one or more of the processes of FIGS. 1 and 6.

FIG. 8 is a block diagram of first and second wafers being separated to produce an SOI structure that is in accordance with one or more of the processes of FIGS. 1 and 6.

FIG. 9 is a block diagram of the first and second wafers of FIG. 5 after being bonded, inverted, and separated to produce an SOI structure that is in accordance with one or more of the processes of FIGS. 1 and 6.

FIG. 10 is a block diagram of the SOI structure of FIG. 9 being edge trimmed that is in accordance with one or more of the process of FIGS. 1 and 6.

FIG. 11 is an SOI structure that is in accordance with embodiments of the present invention.

### DETAILED DESCRIPTION

Reference now will be made in detail to embodiments of the disclosed invention, one or more examples of which are illustrated in the accompanying drawings. Each example is provided by way of explanation of the present technology, not as a limitation of the present technology. In fact, it will be apparent to those skilled in the art that modifications and variations can be made in the present technology without departing from the scope thereof. For instance, features illustrated or described as part of one embodiment may be used with another embodiment to yield a still further embodiment. Thus, it is intended that the present subject matter covers all such modifications and variations within the scope of the appended claims and their equivalents.

Semiconductor on insulator (SOI) structures and methods of making those structures are disclosed. The structures include an electrically insulating layer that is also thermally conductive, such as aluminum nitride, located between a device quality material and a substrate. Such structures reduce the amount of heat that can accumulate in circuitry fabricated on the structure. The structures can be semiconductor wafers that are provided in completed form to serve as the basis for further processing to create an integrated circuit. The integrated circuit can include power devices, power driver and controller circuitry, or other kinds of active heat generating devices.

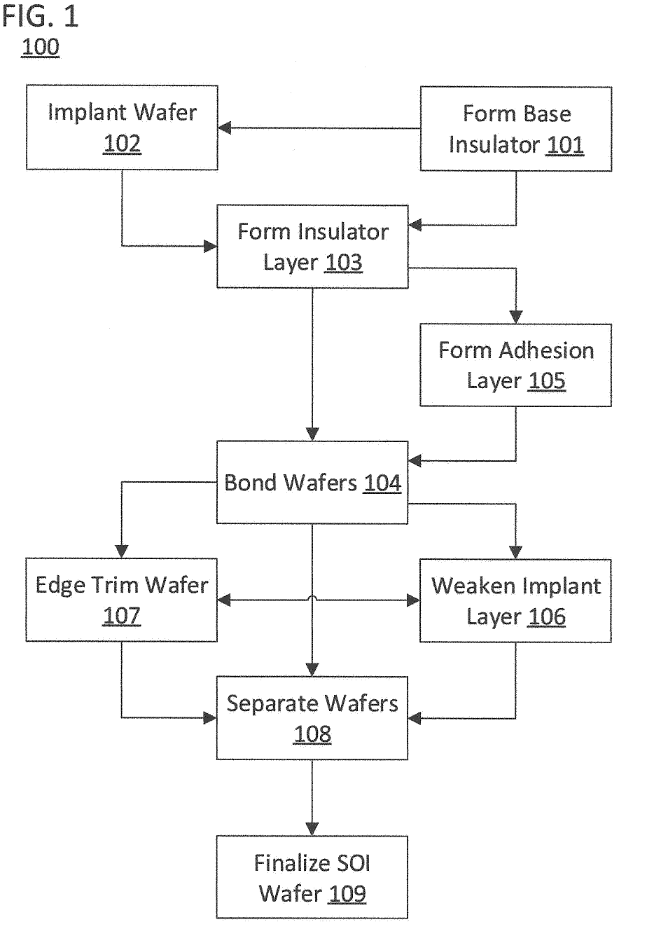

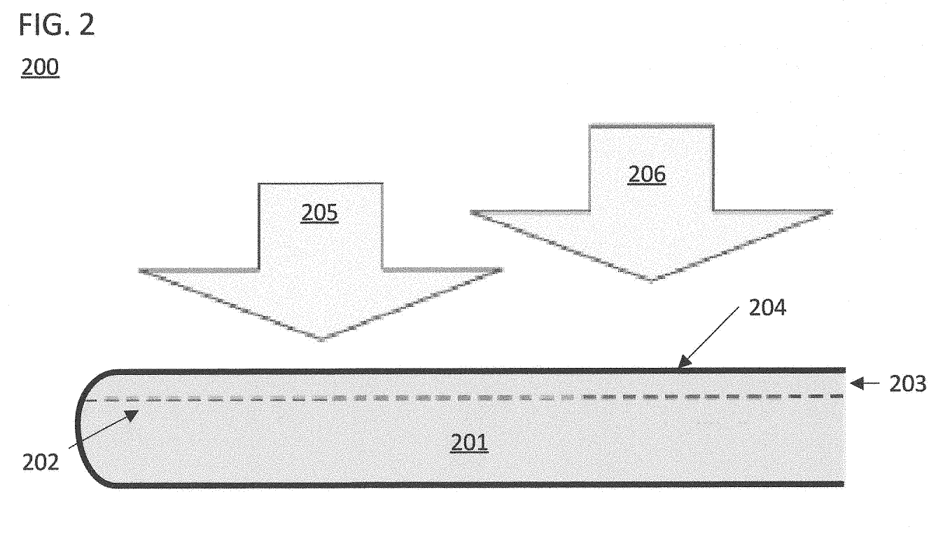

FIG. 1 provides flow chart 100 of a set of methods that can produce SOI structures. FIGS. 2-8 illustrate semiconductor structures that are provided or formed during various stages of one or more of the methods in flow chart 100. Many of the steps on flow chart 100 are optional and are not utilized in every method included in flow chart 100.

Some of the methods in flow chart 100 begin by providing a first wafer. The first wafer can comprise semiconductor material. The semiconductor material can be silicon and can be device quality silicon that can serve as the basis for fabricating active semiconductor devices such as transistors. The first wafer can be a clean silicon donor wafer as utilized in standard SOI fabrication processes. The first wafer can be monocrystalline. The silicon can be doped with a dopant species to activate the silicon. The dopant can be either p-type or n-type. In a particular example, the first wafer can be silicon doped with boron or phosphorous.

Some of the methods in flow chart 100 include step 101 of forming a base insulator on a surface of the first wafer. In other approaches, the first wafer is provided with an insulator already formed over the semiconductor material which can serve as the base insulator. The base insulator can be a silicon dioxide (SiO₂) layer on the surface of the first wafer. In one example, the base insulator is less than 150 nm thick as formed. The base insulator can serve to prevent damage to the surface of the first wafer in approaches where an implant species is implanted into the wafer.

Some of the methods in flow chart 100 include step 102 of implanting an implant species into the first wafer to form an implanted layer below a surface of the semiconductor wafer. Step 102 can be illustrated with reference to semiconductor structure 200 in FIG. 2. The implant can be for purposes of defining a thin layer of semiconductor material. This thin layer of material may ultimately become the active layer of the finished SOI wafer, which is why the first wafer can comprise device quality semiconductor material. In these approaches, the thin layer of material can also be referred to as the donor layer because it is donated from the first wafer. The layer formed below this thin layer of material can be referred to as an implanted layer. As illustrated in FIG. 2, the implant can be a high energy implant of an implant species into first wafer 201 in order to form an implanted layer or implant plane 202 which defines a thin layer of semiconductor material 203. The thin layer of semiconductor material 203 is typically less than 1 μm thick and may comprise device quality semiconductor material. The material can be monocrystalline and be doped with a particular dopant species to activate the semiconductor material. The material can be silicon.

Various implant species can be injected into the semiconductor material to form this layer such as those comprising hydrogen, helium, boron, silicon, and other elements and ions. The implant species can be implanted through a base insulator. As illustrated, semiconductor structure 200 includes base insulator layer 204 of thermally grown SiO₂ through which a first bombardment of hydrogen 205 and a second bombardment of helium 206 are injected. In this combination approach, the helium implant serves to drive the growth of micro-cracks induced by the hydrogen implant. The combination reduces the dose of hydrogen required by an order of magnitude. Regardless of the specific species utilized in step 102, the result is to cause a concentrated implanted layer, which can also be called an implant plane or cleave plane, which has a crystalline structure that is weaker than the crystalline structure of the remainder of the first wafer. In semiconductor structure 200, the implant layer is illustrated as implant layer 202 and is approximately 1100 nm deep into the surface of first wafer 201. As described in more detail below, the implanted layer can crack, blister, split, or rupture in order for the thin layer of material to be separated from the first wafer. Depending upon the method used to remove the thin layer of material, the appropriate term to describe this step may be referred to as exfoliating the layer. The end result is that a thin layer of semiconductor material 203 is removed from first wafer 201.

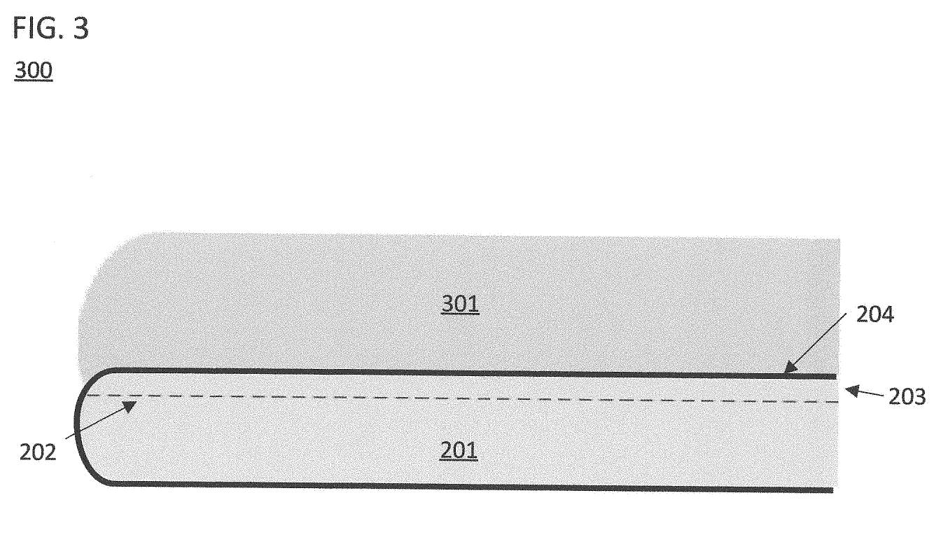

Some of the methods of flow chart 100 can continue with an optional step of thinning or removing the base insulator. For example, layer 204 could be thinned or removed. In these situations, the base insulator could be used to protect the first wafer during step 102 but then be removed to expose the underlying material of the wafer for the following steps. In particular, and with reference to FIG. 3, base insulator 204 could be thinned or removed from semiconductor structure 300 prior to the formation of insulating layer 301 in order to form insulating layer 301 directly on thin layer of semiconductor material 203. Furthermore, the base insulator could be thinned and then reformed to a certain thickness in order to remove a portion of the insulator that was damaged during the insulator step. The process used to reform the insulator could be a thermal growth process for an SiO₂ base insulator using a low temperature process of less than 350° C. If any SiO₂ base insulator, such as base insulator 204, is utilized, certain benefits accrue to approaches in which the layer is originally formed to be, or is thinned to less than 50 nm. Since SiO₂ is somewhat thermally insulative, it is preferable from a thermal dissipation standpoint to thin the layer into this range including removing it entirely or never introducing it in the first place.

The methods of chart 100 will include step 103 of forming an insulator layer. The step can include forming a layer consisting essentially of aluminum nitride (AlN) on the first wafer. The step can also include forming an insulating layer on the first wafer using a low temperature process. The first wafer can include a substrate. For example, in semiconductor structure 300 of FIG. 3, insulating layer 301 is an aluminum nitride that has been formed on the surface of first wafer 201 into which ions have been implanted. Step 103 can be conducted using a low temperature deposition process. As a specific example, the process can be conducted using a low temperature sputtering process. The process can involve RF sputtering, pules DC or AC sputtering, or reactive DC sputtering. However, other low temperature epitaxial, pulsed laser, or chemical vapor deposition processes can be utilized. Low temperature is defined with regards to these steps relative to the high temperature at which implant layer 202 will crack, blister, split, or rupture. As implant layer 202 in FIG. 3 is formed by the dual implant of hydrogen and helium into a device quality silicon, the layer will generally crack at approximately 400° C. so a low temperature deposition step given this implant step is lower than 350° C. More broadly, the term low temperature as used herein refers to a processing step conducted at a temperature below 400° C.

The insulator layer formed in step 103 can be other materials with suitable thermal conductivity and electrical insulation. For example, the insulator layer could be silicon carbide, aluminum oxide, beryllium oxide, diamond, or other ceramic materials. As mentioned, benefits accrue to approaches in which any of these layers are formed via a low temperature sputtering process such as RF sputtering. Any insulator layers with thermal conductivity over 10 watts per meter kelvin and electrical conductivity greater than 10,000 Ω-cm that can be formed via a low temperature process can be formed in step 103 to realize some of the benefits disclosed herein.

The insulating layer formed in step 103 can be an AlN layer of between 1 μm and 4 μm with the precise value being dependent upon the operating frequency of the circuity that will be formed in the final semiconductor structure produced, the thermal characteristic of that circuitry, and the stress profile of the AlN relative to the material of the first wafer. As mentioned previously, the insulating layer can be formed directly on the semiconductor material of the first wafer or it can be formed on a base insulator. To wit, in semiconductor structure 300, insulating layer 301 is formed on base insulator layer 204, but it could also have been formed directly on thin semiconductor layer 203.

Multiple factors can affect a decision to utilize base insulator 204 and the decision on how thick the insulator layer created in step 103 should be. For example, if the insulator layer is made too thin, then the layer is not thermally conductive in the lateral direction and it will make a poor thermal dissipation channel for a wafer in which pockets of heat are created below specific circuitry. Also, if the insulator layer is too thin its electrical properties may not be sufficient to support the circuitry formed in the thin semiconductor layer. However, if the insulator layer is too thick than the performance approaches that of a wafer consisting entirely of the insulator material which is generally not desirable. As described below, the insulator layer will ultimately rest on a substrate of material that is not electrically insulating, but is thermally conductive. For example, the insulator layer could be AlN and the substrate material could be silicon.

In situations where the insulator layer is AlN, the AlN layer should be within the range of 1 μm to 4 μm to provide sufficient electrically insulating performance and thermal dissipation performance. 2 μm of AlN is the practical equivalent to 1 μm of SiO₂ in a traditional SOI wafer in terms of capacitance. This range was also selected with the roughness of the ultimate layer as a consideration. Since the AlN layer will serve as the surface for a bond to another wafer, and the layer overall increases its roughness with increased thickness, it is beneficial to keep the layer thin to provide an adequate bonding surface. Low temperature deposited AlN is an expensive material compared to other insulator layers so keeping the thickness to a minimum decreases the variable cost of a manufacturing line producing semiconductor wafers in accordance with the methods of flow chart 100.

With reference to semiconductor structure 400, the inclusion of a base insulator layer 204 of SiO₂ exhibits certain benefits in that the electrical properties, in particular with reference to recombination, of devices formed in the thin silicon semiconductor layer 203 have similar electrical properties to devices implemented on traditional SOI wafers. Therefore, circuit designs implemented on traditional SOI wafers using SiO₂ as the buried insulator can be more easily ported to a design fabricated using processes of flow chart 100. However, the base insulator layer 204 should be kept less than 50 nm to realize the improved heat performance afforded by insulator layer 301. Thicknesses of 10 nm and greater could provide the electrical properties desired for these specific implementations. These approaches also benefit from the synergy realized by having the base insulator in place to shield first wafer 201 during the implanting of implant species into the wafer to form implant plane 202.

Approaches in which base insulator layer 204 is not included, either by being removed or never formed in the first place, also realize certain benefits that should be considered. When AlN layer 301 is in direct contact with the active silicon of layer 203 the interface recombination velocity is high which may eliminate the need for a body tie to transistors formed in layer 203. This configuration may also improve the linearity of transistors formed in layer 203 and increase their breakdown voltage. As power devices benefit from increased breakdown voltages, approaches in which base insulator layer 204 is not present may be utilized to produce power devices in layer 203 with advantageous characteristics. However, the recombination could be variable. This variability is a reason why base insulator layer 204 of SiO₂ could be beneficially applied to give a known recombination state.

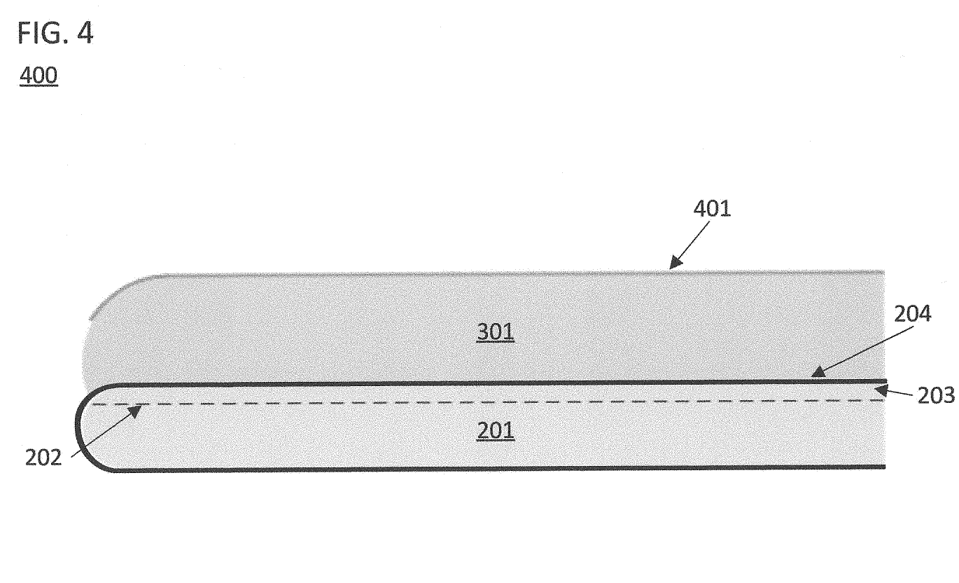

The methods of flow chart 100 can continue with a step 104 of bonding the first wafer to a second wafer. Some of the methods of flow chart 100 can instead continue with an optional step of forming an adhesion layer 105 on a surface of the insulator layer formed in step 103 before proceeding to step 104. In either case, the formation of the insulator layer can be immediately followed by a de-gas anneal prior to the formation of the adhesion layer formation 105 or bonding step 104. As illustrated in semiconductor structure 400 in FIG. 4, the adhesion layer may be amorphous silicon layer 401 applied onto insulator layer 301 via a low temperature deposition process. The adhesion layer could also be silicon nitride (Si₃N₄) or SiO₂ formed using a low temperature PECVD process. The amorphous silicon layer can be formed via RF sputtering. With reference to step 105, the term low temperature has the same meaning as for step 103 and again more broadly means below 400° C. Either the adhesion layer or the insulator layer can then be subjected to a chemical-mechanical planarization (CMP) or other planarizing step to reduce the roughness of the surface of semiconductor structure 400 in order to prepare it for bonding. For example, amorphous silicon layer 401 could be subjected to a CMP process to achieve less than 0.5 nm in root means squared roughness and less than 30 μm of wafer bowing. In another approach, the adhesion layer could be a 1 μm layer of SiO₂ deposited using a PECVD process and subjected to CMP to be less than 1 μm in thickness.

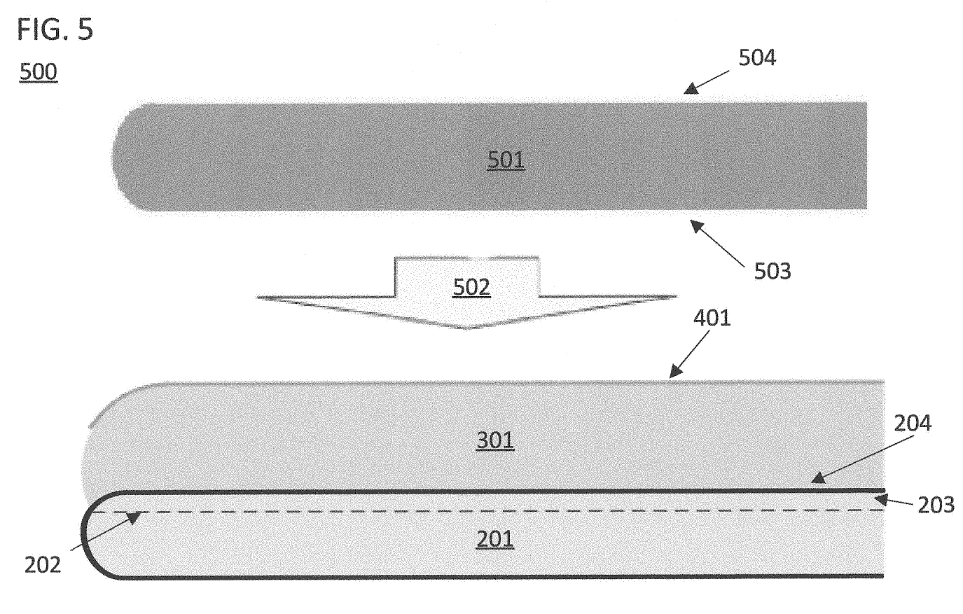

In certain approaches, step 104 will be conducted by bonding a second wafer to the first wafer where the insulating layer is interposed between the substrates of the first and second wafers after the bonding step. In approaches where the first wafer includes an implanted layer, such as implanted layer 202, the layer of insulating material is between the implanted layer and the second wafer after the bonding step. The bonding direction illustrated by reference arrow 502 in FIG. 5 is illustrative of both of these classes of approaches.

In certain approaches, the second wafer 501 will include a substrate. The substrate can be a semiconductor material such as polycrystalline silicon. The second wafer could also be a high resistivity silicon substrate having an electrical resistivity of at least 40 Ω-cm and in some embodiments at least 100 Ω-cm to improve the high frequency (e.g., GHz and above) performance of electronic devices and passive devices formed in thin semiconductor layer 203 in the final semiconductor structure. As illustrated in FIG. 5, second wafer 501 is a high resistivity silicon wafer having a covering of SiO₂ 503. The thickness of the second wafer will depend on its diameter. For a silicon wafer, a 200 mm diameter wafer will have a thickness of roughly 725 μm while a 150 mm diameter wafer will have a thickness of roughly 675 μm. The substrate material can also have a higher thermal conductivity than layer 301 so as to provide a low resistance path to heat diffusing away from the circuitry that will ultimately be formed in thin semiconductor layer 203.

The bonding process conducted in step 104 will depend upon the materials present on the surface of the first and second wafers which together form a bond interface for the bonding process. As mentioned previously, the first wafer could have an adhesion layer 401 on its surface or simply expose the insulating layer 301 to the bond interface. The second wafer could be a homogenous wafer or it could also include a separate outer layer to expose to the bonding interface. For example, the second wafer 501 could be a silicon wafer with a covering of SiO₂ 503. In these examples, the SiO₂ 503 could be removed to present the silicon to the bond interface, or the SiO₂ 503 could be presented to the bond interface. In one approach, a direct silicon bond is achieved between a silicon substrate of the second wafer and a silicon adhesion layer deposited on the insulating layer. With reference to FIG. 5 this would be a direct hydrophobic bond between the silicon of wafer 501 and adhesion layer 401 and would require a low temperature bonding process. This direct silicon-to-silicon bond would have low thermal resistivity. However, any combination of the materials described above for the outer layer of second wafer 501 and adhesion layer 401 may be utilized. For example, if an oxide-to-oxide hydrophilic bond was desired, an adhesion layer of SiO₂ could be used in place of the silicon adhesion layer 401 and the SiO₂ layer 503 of second wafer 501 could be left in place such that both wafers presented SiO₂ to the bond interface. As another example, the first wafer in semiconductor structure might not have adhesion layer 401, and the SiO₂ covering of first wafer 501 could be removed such that the materials presented to the bond interface were AlN and silicon. Such a process could involve de-gassing the nitrogen and argon from insulating layer 301 if insulating layer 301 were formed by a sputtering process. The insulating layer could also be subject to a CMP or other planarizing process prior to this step being conducted. The bonding method in this approach could be conducted using a very high vacuum and high pressure chamber and be conducted at room temperature to keep the thermal mismatch between the silicon and AlN under control. All of the bonding processes can beneficially be conducted at low temperature to avoid disturbing implant plane 202.

In certain approaches in which the bonding interface includes a material that can be selectively etched with respect to the substrate of the second wafer, certain back side treatments can be applied to the semiconductor on insulator wafer to increase the thermal conductivity of the wafer. For example, in an approach where the substrate of the second wafer is silicon and the bonding interface includes SiO₂, a back side etch of surface 504 can be conducted to remove substrate material up to the SiO₂. The SiO₂ or other selectively etched material can then also be thinned or removed. Then, thermally conductive material can be deposited into the excavated region. For example, a layer of copper could be deposited on the back side. In a specific example, a copper lead frame could be formed on the back side of the semiconductor on insulator wafer to further dissipate heat.

After bonding, the methods of flow chart 100 can continue with an optional step 106 of weakening the implant layer, an optional step 107 of edge trimming the combined wafer, or proceeding to a step 108 of separating the wafers. As illustrated, the methods of flow chart 100 can also include both of steps 107 and 106 in either order before proceeding to step 108. Any of these steps can also be preceded by the step of inverting the combined wafer. The edge trim step can involve removing 2-3 mm of material from the edge of the wafer towards the center around the entire circumference of the wafer.

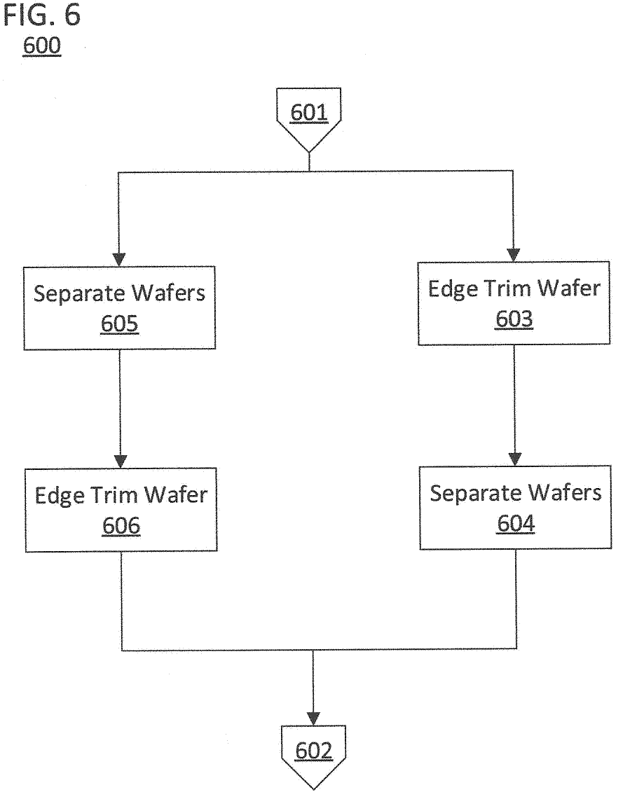

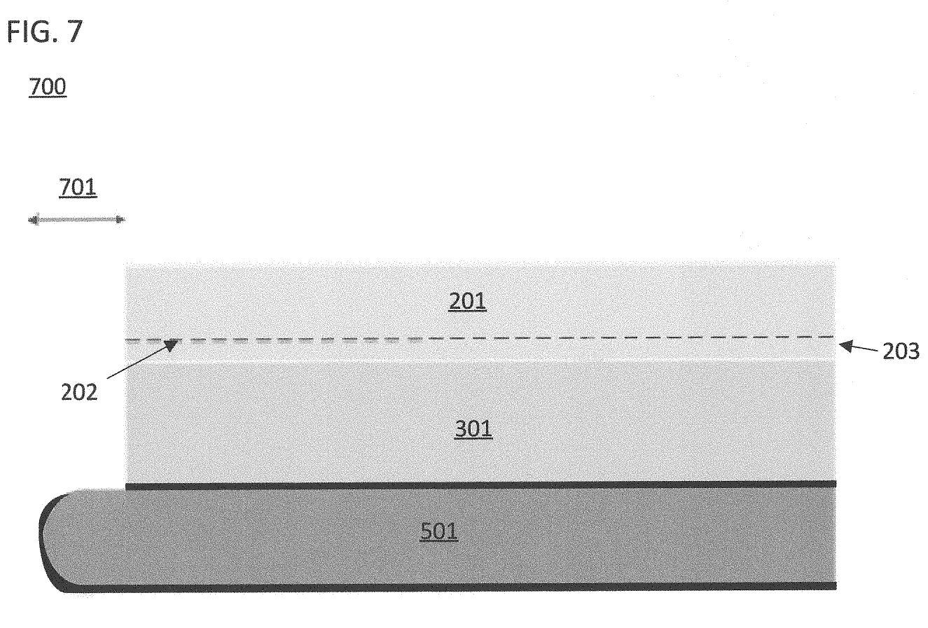

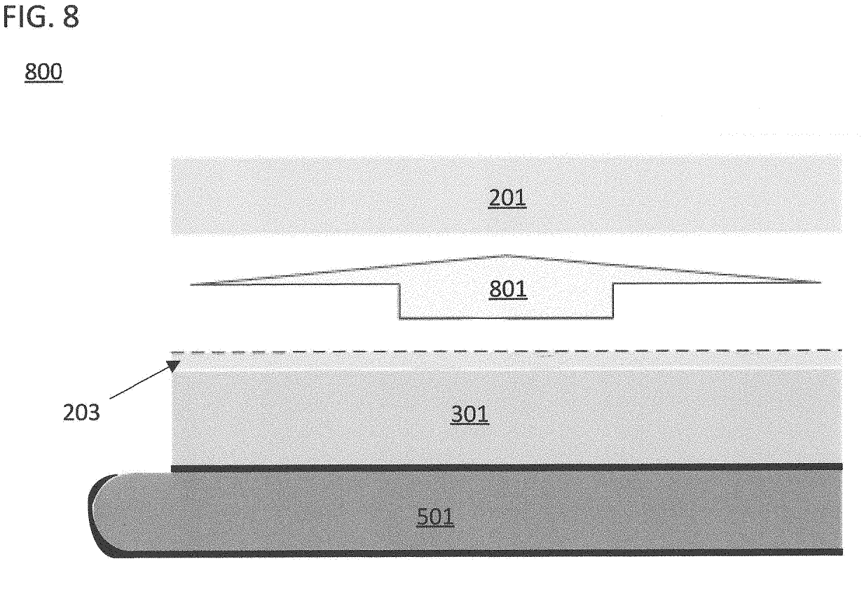

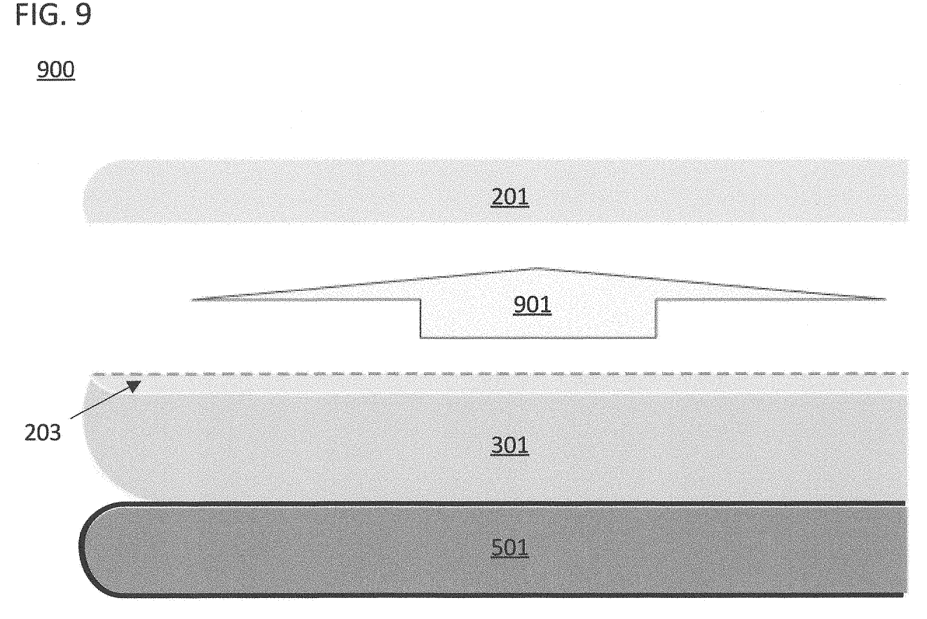

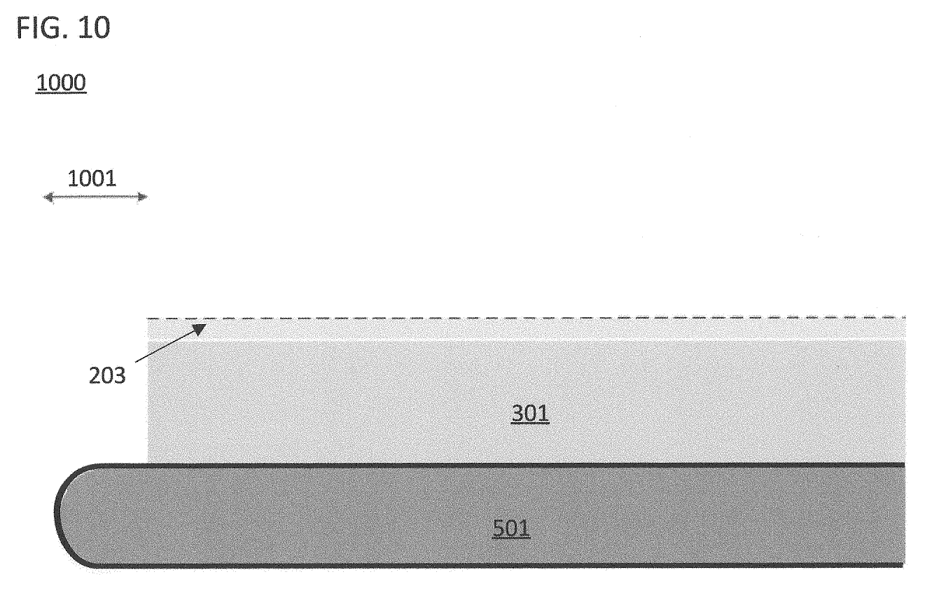

Different variations of the steps in FIG. 1 can be described in more detail with reference to flow chart 600 and FIGS. 6-10. Flow chart 600 illustrates a set of methods that are a subset of the methods in flow chart 100. All of the methods in flow chart 600 include the optional edge trim step. Flow chart 600 begins with off page reference 601 from step 104 in FIG. 1. Flow chart 600 ends with off page reference 602 which returns to step 109 in FIG. 1. The two branches of flow chart 600 differ as to which order the edge trim step and wafer separating step are conducted. Edge trim 603 is conducted prior to separating wafer step 604. Edge trim 606 is conducted after separating wafer step 605. In either situation, separating wafer step 604 or separating wafer step 605 can be broken into two sub-steps with the characteristics of weaken implant layer step 106 and separate wafer step 108. In addition, if separating wafer step 604 is broken into those sub-steps, the weakening implant layer step can be conducted prior to edge trim 603. The branch of flow chart 600 including steps 603 and 604 can be described with reference to FIGS. 7 and 8. The branch of flow chart 600 including steps 605 and 606 can be described with reference to FIGS. 9 and 10.

In certain approaches, an optional edge trim is conducted prior to separating the first and second wafers. The benefit of this approach is that edge effects with implant plane 202 are effectively trimmed out of first wafer 201 during step 603 which results in a cleaner separation during separate wafer step 603. As shown in semiconductor structure 700 of FIG. 7, the combined wafer has been inverted so that first wafer 201 is on the top and second wafer 501 is on the bottom. As shown, edge 701 of the first wafer 201 and the insulating layer 301 is removed via an edge trim procedure. As illustrated, the edge trim procedure is timed and removes a portion of the silicon at the top surface of the second wafer 501. As mentioned, the edge trim leaves a clean well defined edge for the first wafer 201 that can assist in certain approaches for separating the wafers in step 107 or 603. For example, in an exfoliation removal procedure, edge trim 701 will reduce any incidence of edge flaking or peeling during the separation step. As an example of step 106, the combined wafer can be subject to heat cycles to expand the implant species in the implant layer and create a fault line to either cause or prepare for the exfoliation of the thin semiconductor layer 203. For example, if the implant layer was hydrogen and helium implanted into silicon, heat cycles of approximately 450° C. could be applied to create the fault line. As edge effects have been removed by edge trim 701, the remaining implant plane 202 is substantially uniform and will react to those heat cycles in a predictable manner from the edges of the wafer to the center.

In step 108, the two wafers could be separated to form a semiconductor on insulator wafer. During separating step 108, the semiconductor on insulator wafer receives a layer of semiconductor material from the first wafer. After the separating step, the semiconductor on insulator wafer includes the thin layer of semiconductor material, the insulator layer, and the substrate from the second wafer. Effectively, during the separation, thin semiconductor layer and insulator layer are effectively transferred from the first wafer to the second wafer. The wafers could be separated by inducing a fracture in the implant layer via the application of physical force directed at the implant layer, continued heat cycling to expand the implant species, or the application of physical force across the entire wafer in an upward direction.

FIG. 8 illustrates an example of conducting separating step 108 in accordance with step 604 and with reference to semiconductor structure 800. As illustrated, first wafer 201 is removed in a direction marked by reference line 801. The approach illustrated in FIG. 8 is in accordance with step 604 because it is conducted after an edge trim step. As mentioned previously, the resulting wafer is less likely to be corrupted by edge effects. However, first wafer 201 will likely need to be discarded because it has been processed with an edge trim procedure. This is not the best result from a cost of materials perspective because the only material that will be used from first wafer 201 is the thin semiconductor layer 203 that is left behind.

FIG. 9 illustrates an example of conducting separating step 108 in accordance with step 605 and with reference to semiconductor structure 900. As illustrated, first wafer 201 is removed in a direction marked by reference line 901. The approach illustrated in FIG. 9 is in accordance with step 605 because it is conducted prior to an edge trim step. Wafer 201 is therefore removed without having undergone an edge trim. The subsequent edge trim 1001 of the thin semiconductor layer 203 and insulating layer 301 is illustrated in FIG. 10 with reference to semiconductor structure 1000. In order to assure a clean separation as shown by reference line 901, it may be necessary to modify implant step 102 to assure that implanting is done all the way to the edge of the wafer, or to over scan the edge on implant. For instance, in certain implanters clamps shadow the implant around the edge, and the implant may need to be compensated to adjust for this fact. Notably, if approaches that utilize steps 603 and 604 are applied instead, any clamps that may be present are less of an issue and do not need to be compensated for.

The thin semiconductor layer 203 that is left behind after certain implementations of step 108 is a thin strip of silicon that is approximately 1.1 μm thick. After separation, a high temperature anneal can be conducted to anneal out any damage to the thin semiconductor layer caused during the implant step. This high temperature anneal can also serve to improve the bond strength of a silicon-to-silicon bond in situations where both the first wafer and second wafer presented silicon to the bond interface. The top surface of the semiconductor on insulator wafer can then be thinned down to the required thickness. In certain approaches, the finalized thin semiconductor layer will be less than 1 μm thick. In other approaches, the finalized thin semiconductor layer can be less than 100 nm thick and can enable the fabrication of fully depleted devices in the active layer.

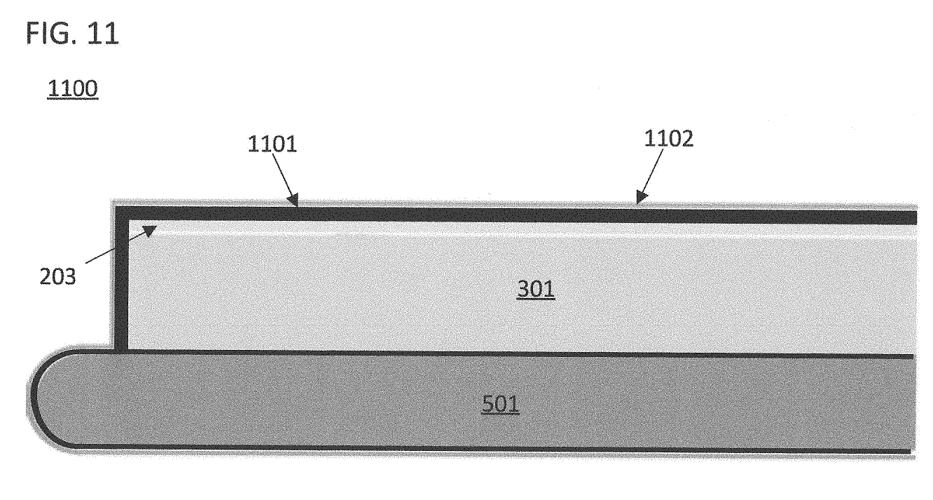

The methods of flow chart 100 can finish with step 109 in which the semiconductor on insulator wafer is finalized. This step can include depositing a protecting layer of SiO₂ on the wafer which can be done using PECVD. Next a protective layer of silicon nitride or thick poly silicon can deposited to protect the edge of the wafer during the high temperature processing such as the field oxidation to prevent excessive bird's beak and wafer warping. The need for stress balancing increases with the thickness of insulating layer 301 relative to the thickness of the substrate of second wafer 501. With an insulating layer thickness of 1 μm to 4 μm and a substrate thickness correspondingly varying from of 675 μm to 725 μm, a silicon nitride or SiO₂ layer of less than 500 nm, such as 400 nm, is generally sufficient. However, since the thick poly silicon will partially oxidize during later high temperature processing steps, such as the introduction of field oxide, the required thickness of polysilicon is larger with all else held equal. In the specific example of FIG. 11, semiconductor structure 1100 includes SiO₂ layer 1101 and protective layer 1102 and is a finalized semiconductor on insulator wafer fabricated in accordance with a method in the set of methods in flow chart 100.

Approaches described above enable the thin semiconductor layer to be less than 1 um thick, and can enable the thin semiconductor layer to be less than 100 nm thick to enable the fabrication of fully depleted devices in the active layer. Also, low temperature deposition of AlN may form insulator layers with mean crystal sizes in excess of 100 nm and below 1000 nm, 500 nm or 250 nm, but will still provide sufficient electrical insulation for the devices formed in the thin semiconductor layer. Generally speaking, the low temperature approaches described above will result in AlN layers that consist of equiaxed small crystals near the substrate surface and the growth of columns with the rise of layer thickness, with mean crystal sizes that vary inversely with the temperature of deposition. Note that here the term “substrate” refers to the substrate of first wafer 201, as it serves as the substrate for the formation of insulating layer 301. In particular, the formation of an insulating layer of AlN that is at least 4.9 μm thick using RF sputtering with a substrate that is left at room temperature (˜25° C.) will result in an insulating layer with mean crystal sizes from 900 nm to 1000 nm. As another example, the formation of an insulating layer of AlN that is at least 4.5 μm thick using RF sputtering and a substrate heated to at above 200° C. will result in an insulating layer with mean crystal sizes from 120 nm to 150 nm. In contrast, approaches using high temperature deposition techniques result in insulating layers with far smaller crystal sizes regardless of the thickness of the AlN layer. As a specific example, related approaches with substrates heated to 750° C. result in insulating layers of AlN that are at least 5 μm thick with a mean crystal size of 20 nm to 40 nm. However, using the approaches disclosed herein, it is possible to create an AlN layer that is sufficiently thick and exhibits a sufficiently small crystal size to provide the benefits of SOI technology to devices in the thin semiconductor layer of the finished wafer while still being formed using a low enough temperature process to avoid damaging implant plane 202.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those skilled in the art, without departing from the scope of the present invention, which is more particularly set forth in the appended claims.

What is claimed is:

1. A process comprising:
implanting an implant species into a first semiconductor wafer to form an implanted layer below a surface of the first semiconductor wafer;
forming a layer of electrically insulating material on the surface using a low temperature sputtering process;
bonding a second wafer to the first wafer, wherein the layer of insulating material is between the implanted layer and the second wafer after the bonding step; and
separating the first and second wafers at the implanted layer to form a semiconductor on insulator wafer;
wherein, after the separating step, the semiconductor on insulator wafer includes a layer of semiconductor material from the first semiconductor wafer, the layer of electrically insulating material, and the second wafer.

2. The process of claim 1, wherein:
the layer of electrically insulating material in the semiconductor on insulator wafer is a layer of aluminum nitride with a mean crystal size greater than 100 nanometers; and
the layer of semiconductor material in the semiconductor on insulator wafer is a layer of monocrystalline silicon.

3. The process of claim 2, wherein:
the layer of electrically insulating material in the semiconductor on insulator wafer is between 1 and 4 micrometers thick; and
the layer of semiconductor material in the semiconductor on insulator wafer is less than 1 micrometer thick.

4. The process of claim 2, further comprising:
prior to the implanting step, forming a base insulator layer on the first semiconductor wafer; and
wherein the implanting of the implant species is conducted through the base insulator layer.

5. The process of claim 4, further comprising:
after the forming of the base insulator layer step, implanting a second implant species into the first semiconductor wafer to form the implanted layer below the surface of the first semiconductor wafer;
wherein the implant species is hydrogen;
wherein the second implant species is helium; and
wherein the base insulator layer is thermally grown silicon dioxide.

6. The process of claim 4, further comprising:
prior to forming the layer of electrically insulating material, thinning the base insulator layer to a thickness of less than 50 nanometers.

7. The process of claim 2, wherein:
the low temperature sputtering process is conducted at a temperature of less than 350° C.

8. The process of claim 7, further comprising:
the low temperature sputtering process is an RF sputtering process.

9. The process of claim 2, further comprising:
after forming the layer of electrically insulating material, forming an adhesion layer of polysilicon on the first semiconductor wafer;
wherein the adhesion layer is located at a bond interface during the bonding step.

10. The process of claim 2, further comprising:
after forming the layer of electrically insulating material, forming an adhesion layer on the first semiconductor using a low temperature deposition;
wherein the adhesion layer is located at a bond interface during the bonding step; and
wherein the adhesion layer is one of SiO₂ and Si₃N₄.

11. A process comprising:
forming a layer consisting essentially of aluminum nitride on a first wafer, wherein the first wafer includes a substrate;
bonding a second wafer to the first wafer, wherein the layer consisting essentially of aluminum nitride is interposed between the substrate and the second wafer after the bonding step; and
separating the first and second wafers to form a semiconductor on insulator wafer;
wherein, during the separating step, the semiconductor on insulator wafer receives a layer of semiconductor material from the second wafer; and
wherein, after the separating step, the semiconductor on insulator wafer includes the layer of semiconductor material, the layer consisting essentially of aluminum nitride, and the substrate.

12. The process of claim 11, further comprising:
implanting an implant species into the second semiconductor wafer to form an implanted layer below a surface of the second semiconductor wafer;
wherein the layer of semiconductor material in the semiconductor on insulator wafer is a layer of monocrystalline silicon; and
wherein the layer of semiconductor material in the semiconductor on insulator wafer has a thickness of less than 1 micrometer.

13. The process of claim 11, wherein:
the layer consisting essentially of aluminum nitride is between 1 and 4 micrometers thick.

14. The process of claim 11, further comprising:
prior to the bonding step, forming an adhesion layer on the layer consisting essentially of aluminum nitride on the first wafer;
wherein the adhesion layer includes SiO₂.

15. The process of claim 14, further comprising:
prior to the bonding step, planarizing the adhesion layer;
wherein the adhesion layer is less than 1 micrometer thick after being planarized.

16. The process of claim 11, wherein:
a mean crystal size in the layer consisting essentially of aluminum nitride is greater than 100 nanometers.

17. A semiconductor on insulator wafer comprising:
a layer of device quality silicon that is less than 1 micrometer thick;
a layer of silicon dioxide that is under 50 nanometers thick located under the layer of device quality silicon and in contact with the layer of device quality silicon;
a layer of aluminum nitride that is 1 micrometer to 4 micrometers thick under the layer of silicon dioxide and in contact with the layer of silicon dioxide; and
a substrate of silicon located below the layer of aluminum nitride;
wherein a mean crystal size in the aluminum nitride layer is greater than 100 nanometers.

18. The semiconductor on insulator wafer of claim 17 wherein:
the layer of device quality silicon is less than 100 nanometers thick.

19. A semiconductor on insulator wafer comprising:
a layer of device quality silicon that is less than 1 micrometer thick;
a layer of aluminum nitride that is 1 micrometer to 4 micrometers thick under the layer of device quality silicon and in contact with the layer of device quality silicon; and
a substrate of silicon located below the layer of aluminum nitride;
wherein a mean crystal size in the aluminum nitride layer is greater than 100 nanometers.

20. The semiconductor on insulator wafer of claim 19 wherein:
the layer of device quality silicon is less than 100 nanometers thick.
